(19) United States
(12) Patent Application Publication
(10) Pub. No.: US 2025/0133698 A1
(43) Pub. Date: Apr. 24, 2025

(54) ELECTRONIC DEVICE COOLING ARCHITECTURE IMPLEMENTING THERMALLY CONDUCTIVE PLASTIC SUPPORTS

(71) Applicant: Intel Corporation, Santa Clara, CA (US)

(72) Inventors: Chi Chou Cheng, Taipei (TW); Jeff Ku, Taipei (TW); Chung Jen Ho, New Taipei (TW); Chihtsung Hu, New Taipei (TW); Tsung-Kai Lin, New Taipei (TW)

(21) Appl. No.: 18/989,639

(22) Filed: Dec. 20, 2024

(51) Int. Cl. H05K 7/20; G06F 1/20

(52) U.S. Cl. CPC H05K 7/20336; G06F 1/203

(57) ABSTRACT

An electronic device is provided that implements thermally conductive plastic supports that may replace the typical use of “feet” used in conventional electronic devices. The thermally conductive supports may extend through the bottom chassis cover (e.g. the “D cover”) of the electronic device, and be mechanically and thermally coupled to a heat pipe that is in turn coupled to a heat source for which thermal regulation is utilized. The thermally conductive plastic supports may provide a heat path from the heat source to the bottom chassis cover and, when the electronic device is disposed on a surface, an additional heat path may be provided from the heat source to this surface.

### TECHNICAL FIELD

The disclosure described herein generally relates to electronic device cooling solutions and, in particular, to electronic device cooling architectures that implement thermally conductive plastic supports.

### BACKGROUND

As market demands continue to drive electronic devices to be thinner and lighter, fanless designs are often used to meet these needs. However, fanless designs are generally inadequate to provide cooling for higher thermal design power (TDP) operations, such as those at or above 15 W for instance. Further complicating this issue, the dissipation of heat for fanless designs presents considerable difficulty to ensure that skin temperature specifications are met. Thus, to meet and pass surface temperature specifications, the TDP is often reduced during use, in turn reducing performance. Therefore, current fanless designs for electronic devices are inadequate.

### BRIEF DESCRIPTION OF THE DRAWINGS/FIGURES

The accompanying drawings, which are incorporated herein and form a part of the specification, illustrate the present disclosure and, together with the description, further serve to explain the principles and to enable a person skilled in the pertinent art to make and use the techniques discussed herein.

In the drawings, like reference characters generally refer to the same parts throughout the different views. The drawings are not necessarily to scale, emphasis instead generally being placed upon illustrating the principles of the disclosure. In the following description, reference is made to the following drawings, in which:

FIG. 1 illustrates an electronic device, in accordance with the disclosure;

FIG. 2 illustrates an environment including an electronic device in a cutaway view that is disposed on a surface, in accordance with the disclosure;

FIGS. 3A-3B illustrate different views of a cooling module that forms part of a cooling system of an electronic device, in accordance with the disclosure;

FIGS. 4A-4D illustrate various views of an electronic device, in accordance with the disclosure;

FIGS. 5A-5C illustrate various views of the interfaces between the cooling module and the electronic device, in accordance with the disclosure;

FIG. 6 illustrates a process flow, in accordance with the disclosure;

FIG. 7 illustrates the temperature of a thermally conductive plastic support and D cover of an electronic device, in accordance with the disclosure;

FIG. 8A illustrates a temperature of various components of an electronic device over time without the use of a conductive plastic support and cooling system as discussed herein;

FIG. 8B illustrates a temperature of various components of an electronic device over time with the use of a conductive plastic support and the cooling system as discussed herein, in accordance with the disclosure;

FIG. 9 illustrates the temperature of various components of an electronic device over time with the use of a conductive plastic support and the cooling system as part of a fanless design, in accordance with the disclosure; and

FIGS. 10A illustrates an IR thermal image of an electronic device for a fanless design, in accordance with the disclosure; and

FIGS. 10B illustrates an IR thermal image of an electronic device for a fan-based design, in accordance with the disclosure.

The present disclosure will be described with reference to the accompanying drawings. The drawing in which an element first appears is typically indicated by the leftmost digit(s) in the corresponding reference number.

### DETAILED DESCRIPTION

The following detailed description refers to the accompanying drawings that show, by way of illustration, exemplary details in which the disclosure may be practiced. In the following description, numerous specific details are set forth in order to provide a thorough understanding of the present disclosure. However, it will be apparent to those skilled in the art that the various designs, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring the disclosure.

Again, current solutions to implement fanless designs for electronic devices have various drawbacks. For instance, conventional designs may implement an aluminum plate or vapor chamber that contacts the system on a chip (SoC) and provides heat dissipation. However, these designs fail to address the issue with the C and D covers of laptop computers overheating at 10 W TDP by way of exceeding skin temperature regulatory thresholds. Furthermore, because the SoC heat is transferred to the aluminum plate or vapor chamber through heat transfer, when the heat dissipation area is insufficient the heat in the electronic device will continue to rise, causing the surface temperature to further increase. This issue is further complicated by conventional fanless electronic device designs that implement such passive cooling systems, which lack a good heat transfer path.

The disclosure addresses these issues by providing a conductive heat path between the heat source of an electronic device, such as the SoC for instance, and the bottom chassis cover (e.g. the “D cover) of the electronic device. This may be accomplished, as further discussed below, via the use of thermally conductive plastic supports that may replace the typical use of “feet” used in conventional electronic devices. For instance, the thermally conductive supports may extend through the bottom chassis cover of the electronic device, and be mechanically and thermally coupled to a heat pipe that is, in turn, coupled to a heat source for which thermal regulation is implemented. Thus, the thermally conductive plastic supports may provide a heat path from the heat source to the bottom chassis cover and, when the electronic device is disposed on a surface, an additional heat path may be provided from the heat source to this surface.

Furthermore, in this context it is noted that the aspects as discussed in further detail may be implemented as part of a pure fanless design or, alternatively, as part of a fanless capable design. In this context, fanless designs may include electronic devices having no fan components, and thus the aspects as described herein may be implemented in place of one or more conventional fans. Alternatively, electronic device designs may include one or more fans, which may controlled by the electronic device system and optionally be selectively turned on or off based upon working and/or thermal conditions. For instance, when all fans are turned off, such electronic devices may temporarily function as a fanless design. Thus, such electronic device designs may be referred to herein as “fanless capable” or a “hybrid fanless” design. The aspects described herein may be implemented as part of such hybrid fanless designs by replacing one or more fans or, alternatively, by supplementing the thermal management provided by one or more fans.

### I. Cooling System Architecture and Operation

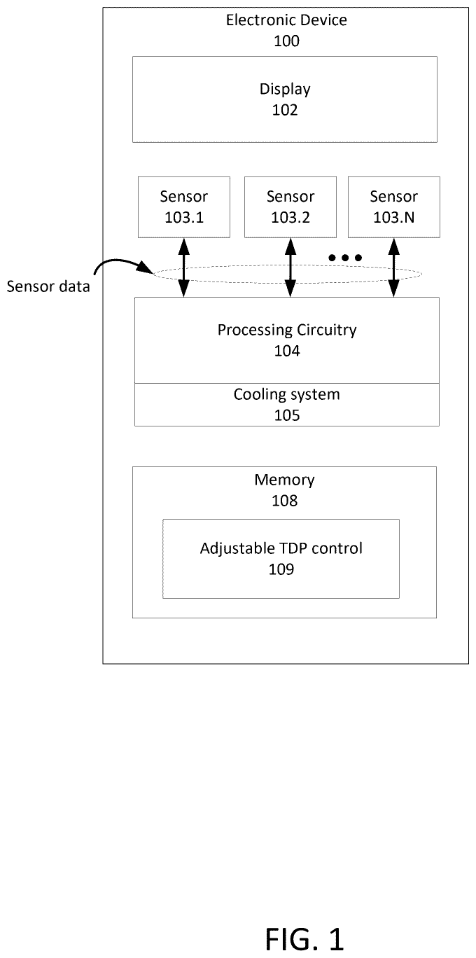

To this end, FIG. 1 illustrates an electronic device, in accordance with the disclosure. The electronic device 100 may be identified with any suitable type of device that implements one or more of the cooling systems as further discussed herein. The electronic device 100 may be identified with any suitable type of electronic device in which fanless or fanless capable cooling is utilized with respect to any suitable number and/or type of heat source. Thus, the electronic device 100 may be identified with a laptop computer (such as a fanless or fanless capable laptop), a wireless device, a user equipment (UE), a mobile phone, a tablet, a wearable device, etc. Additionally or alternatively, and as further discussed herein, the electronic device 100 may be configured to operate at a thermal design power (TDP) of up to or in excess of 15 Watts.

The electronic device 100 may have any suitable number of chassis covers, with the components of the electronic device 100 being disposed within these chassis covers. For instance, when implemented as a laptop computer, the electronic device may have an A, B, C, and D cover, as is generally known. The D cover in this scenario may be implemented as the bottom chassis cover of the electronic device 100.

The electronic device 100 may comprise a display 102, which may form part of a display assembly such as a display cover. The display 102 may be implemented as or form part of any suitable type of display assembly such as a light-emitting diode (LED) display, a liquid crystal display (LDC), an organic LED display, a Twisted Nematic (TN) display, an In-Plane Switching (IPS) display, etc.

The electronic device 100 may comprise any suitable number of sensors 103.1-103.N. Each of the sensors 103.1-103.N may be implemented as any suitable type of sensor as discussed herein, each being configured to generate sensor data in accordance with a particular type of sensor measurement. The sensors 103.1-103.N may be identified with existing sensors of the electronic device 100 (such as one forming part of one or more integrated device sensors), or dedicated sensors used for the adjustment of the power profile of the electronic device 100 and an accompanying TDP setting, as discussed herein. Each of the sensors 103.1-103.N is configured to generate sensor data as noted herein, which may be transmitted to the processing circuitry 104.

The electronics device 100 may further comprise processing circuitry 104, which may be configured as any suitable number and/or type of computer processors, and which may function to control the electronic device 100 and/or other components of the electronic device 100, such as the adjustment of the power profile of the electronic device 100. The processing circuitry 104 may be identified with one or more processors (or suitable portions thereof) implemented by the electronic device 100. The processing circuitry 104 may be identified with one or more processors such as a host processor, a microcontroller, a digital signal processor, one or more microprocessors, a central processing unit (CPU), graphics processors such as a graphics processing unit (GPU), baseband processors, microcontrollers, an application-specific integrated circuit (ASIC), part (or the entirety of) a field-programmable gate array (FPGA), etc. The processing circuitry 104 may be identified, in a non-limiting and illustrative scenario, with one or more portions (or the entirety) of an SoC, for which thermal regulation is implemented in accordance with the cooling system 105 as discussed herein.

The processing circuitry 104 may be configured to carry out instructions to perform arithmetical, logical, and/or input/output (I/O) operations, and/or to control the operation of one or more components of electronic device 100 to perform various functions as described herein. The processing circuitry 104 may include one or more microprocessor cores, memory registers, buffers, clocks, etc., and may generate electronic control signals associated with the components of the electronic device 100 to control and/or modify the operation of these components. The processing circuitry 104 may communicate with and/or control functions associated with the memory 108, as well as any other components of the electronic device 100. Thus, the processing circuitry 104 may control or cause other components to control the adjustment of the power profile of the electronic device 100 in response to one or more triggering conditions being met, as discussed herein.

The electronic device 100 comprises a cooling system 105, which may comprise a passive (such as a fanless) cooling system and include the various components as discussed in further detail herein. The cooling system 105 may be coupled to one or more portions of the processing circuitry 104 or to the entirety of the processing circuitry 104. The cooling system 105 may be coupled to one or more heat sources of the electronic device 100 in addition to or instead of the processing circuitry 104. The cooling system 105 may include one or more thermally conductive plastic supports that enable a conductive heat path from the processing circuitry 104 and/or the heat sources to which the cooling system 105 is coupled to the bottom cover of the electronic device and/or a surface upon which the electronic device 100 is disposed, as further noted herein.

The memory 108 is configured to store data and/or instructions such that, when executed by the processing circuitry 104, cause the electronic device 100 to perform various functions such as controlling, monitoring, and/or regulating the operation of the electronic device 100, analyzing the sensor data, determining whether a triggering condition has been met, generating the control signals for the adjustment of the power profile of the electronic device 100, etc., as discussed in further detail herein. The memory 108 may be implemented as any suitable type of volatile and/or non-volatile memory, including read-only memory (ROM), random access memory (RAM), flash memory, a magnetic storage media, an optical disc, erasable programmable read only memory (EPROM), programmable read only memory (PROM), etc.

The memory 108 may be non-removable, removable, or a combination of both. The memory 108 may be implemented as a non-transitory computer readable medium storing one or more executable instructions such as logic, algorithms, code, etc. The instructions, logic, code, etc., stored in the memory 108 are represented by the various modules as shown. The processing circuitry 104 may execute the instructions stored in the memory 108, which are represented as the various modules and further discussed below, to enable any of the techniques as described herein to be functionally realized.

The adjustable TDP control module 109 may store computer-readable instructions that, when executed by the processing circuitry 104, enable the processing circuitry 104 to perform any of the functions as described herein with respect to the adjustment of the power profile of the electronic device 100. Thus, the processing circuitry 104 may execute the instructions stored in the adjustable TDP control module 109 to receive and analyze the sensor data from any suitable components of the electronic device 100, to determine whether one or more triggering conditions have been met, to generate control signals to adjust the power profile of the electronic device 100, etc. the memory 108 may store additional executable instructions, such as those typically associated with electronic devices, e.g. an operating system.

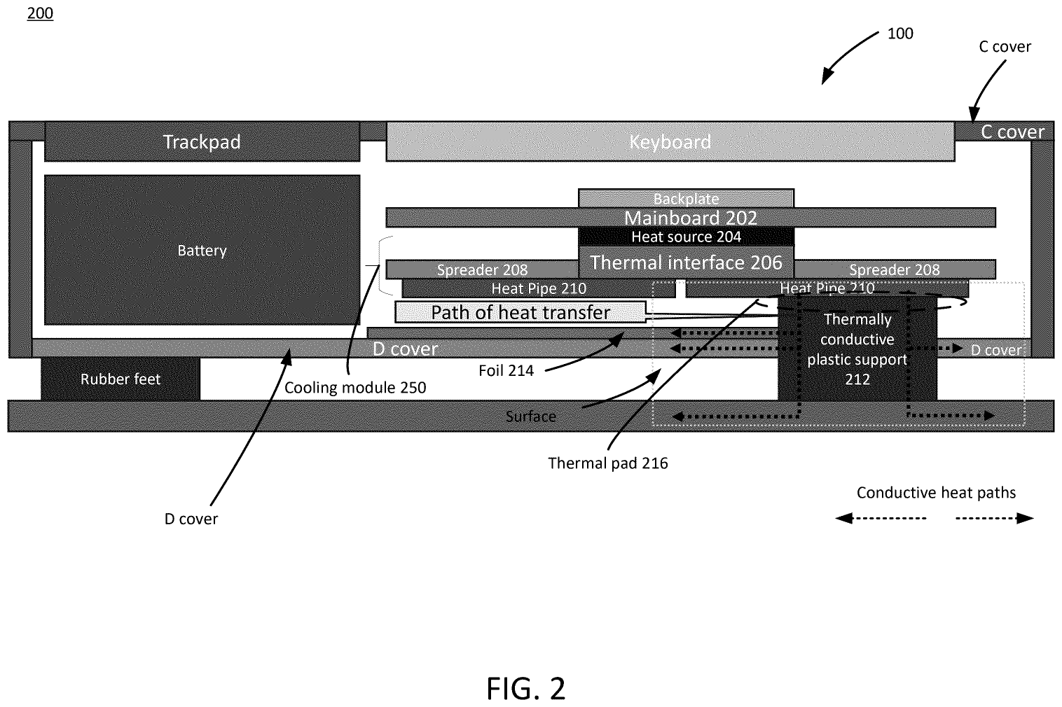

FIG. 2 illustrates a cutaway view of various components of the electronic device 100, in accordance with the disclosure. The environment 200 as shown in FIG. 2 thus includes the electronic device 100 as well as a surface on which the electronic device 100 is disposed. The view of the electronic device 100 as shown in FIG. 2 illustrates several components in further detail, and also illustrates the C and D covers that represent the upper and lower chassis covers, respectively, of the electronic device 100. The electronic device 100 may include additional or alternate components than those shown in FIG. 2, such as A and B covers, for instance, or other components that electronic devices typically have, which are not shown in the Figures for purposes of brevity.

The electronic device 100 includes a mainboard 202 upon which various electronic components are disposed that are implemented for the overall operation of the electronic device 100, which may include a heat source 204. Again, the heat source 204 may be identified with any suitable components of the electronic device 100 for which passive cooling is used to regulate the temperature thereof. As some non-limiting and illustrative scenarios, the heat source 204 may comprise a CPU, chip, and/or a portion of an SoC implemented by the electronic device 100.

The electronic device 100 also includes a thermal interface 206, which may be mechanically and thermally coupled to the heat source 204. Thus, the thermal interface 206 may be comprised of any suitable type of one or more materials having a suitably high thermal conductivity for this purpose. In a non-limiting and illustrative scenario, the thermal interface 206 may comprise a solid copper block or other solid material made of one or more thermally conductive materials. Additionally, the thermal interface 206 may comprise a suitable thermal interface material such as thermal paste or pad, which may couple the thermal interface 206 to the heat source 204 as well as to the heat spreader 208, and the one or more heat pipes 210. Thus, the thermal interface 206, the heat spreader 208, the one or more heat pipes 210, as well as any other suitable materials used to thermally couple these components to one another, may comprise a cooling module 250, as shown in FIG. 2, which forms part of the cooling system 105 as shown in FIG. 1.

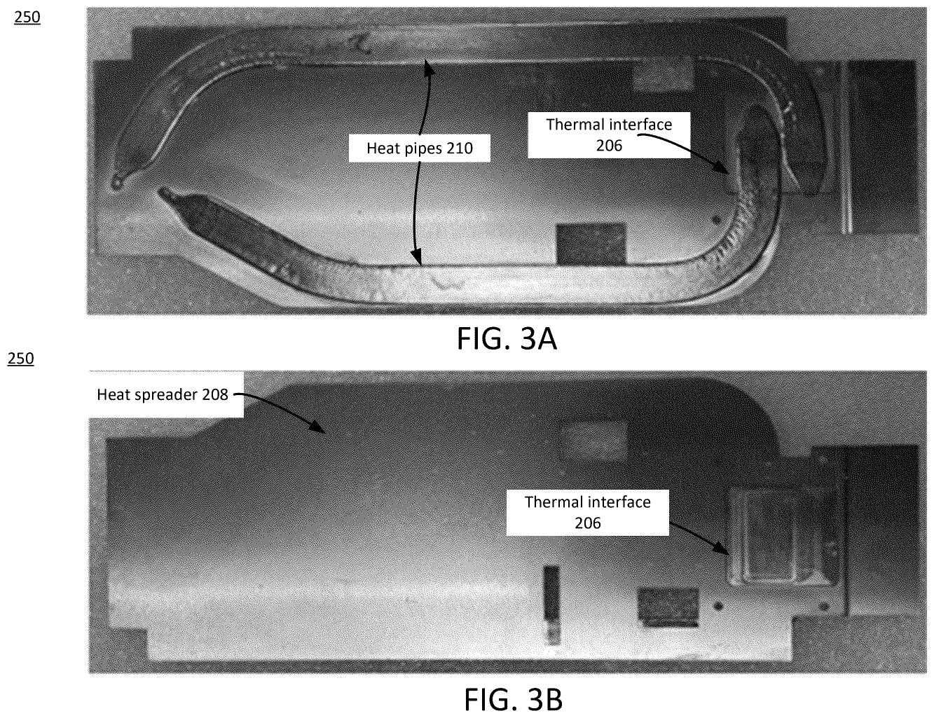

Thus, the cooling module 250 may be identified with part of the cooling system 105 as shown and discussed above with respect to FIG. 1, with additional detail regarding the cooling module 250 being illustrated in FIGS. 3A-3B. For instance, the cooling module 250 as shown in FIGS. 3A-3B includes two heat pipes 210, although this is a non-limiting illustration and the cooling module 250 may have additional or fewer heat pipes. The heat pipes 210 may be configured to be thermally and mechanically coupled to the heat source 204 (such as via the thermal interface 206) and the heat spreader of 208 of the electronic device 100 to facilitate a thermal transfer of heat from the heat source 204 by way of thermal conduction, thereby forming a thermally conductive heat path. The heat pipes 210 may be made of any suitable materials for this purpose, such as copper, and may include any suitable type of wicking material, phase change material, etc. Thus, the heat pipes 210 may be comprised of any suitable construction, including those identified with known heat pipe designs and implementations.

The cooling module 250 as shown in FIGS. 3A-3B also includes the thermal interface 206 as shown in FIG. 2, with the side as shown in FIG. 3A being coupled mechanically and thermally to the heat pipes 210. The side of the thermal interface 206 as shown in FIG. 3B is thus configured to be thermally and mechanically coupled to the heat source 204 (not shown). The cooling module 250 also includes the heat spreader 208, which may be any suitable material, size, and shape configured to spread the heat transferred from the heat pipes 210 across its surface in a relatively uniform manner. Thus, the heat spreader 208 may be implemented as a metal or other suitable thermally conductive material having a planar shape, such as the metal plate as shown in FIGS. 3A-3B. In a non-limiting and illustrative scenario, the heat spreader 208 may be implemented as an aluminum plate. In this way, the heat spreader 208 is configured to spread heat generated by the heat source 204 and to form a thermally conductive heat path across the heat source 204 by way of the thermal coupling between the heat source 204, the thermal interface 206, the heat pipes 210, and the heat spreader 208. Again, these components may be mechanically and thermally coupled to one another in any suitable manner to achieve this functionality.

Returning now to FIG. 2, the cooling system 105 may optionally include a thermally conductive foil layer 214, which may comprise copper foil for instance. The thermally conductive foil layer 214 is not required, but may be particularly useful when the cooling system 105 is installed as a retrofit to an electronic device to replace a fan-based cooling system with a fanless or a fanless capable design, as the thermally conductive foil layer 214 may already be present in such systems and may facilitate improved thermal performance.

The cooling system 105 of the electronic device 100 may include one or more thermally conductive plastic supports 212. The bottom chassis cover (e.g. the D cover as shown) may include one or more openings, which are shown and discussed in further detail below. The one or more thermally conductive plastic supports 212 may be configured to extend through these openings and to contact one or more of the heat pipes 210 at one or more locations, as further discussed herein. Thus, the thermally conductive plastic support 212 may replace the conventional use of non-thermally conductive components that are typically mounted to the bottom chassis cover, such as a “foot” that may comprise a support for the electronic device when resting on a surface. That is, the thermally conductive plastic support 212 may be implemented as a supportive foot structure of the electronic device 100, which is configured to contact the surface upon which the electronic device 100 is disposed, as shown in FIG. 2 and further discussed herein.

However, although the thermally conductive plastic support 212 may comprise such a supportive foot for the electronic device 100, in contrast with conventional materials used for this purpose, the thermally conductive plastic support 212 may be comprised of any suitable polymer or other material having a suitably high thermal conductivity to facilitate the formation of the heat paths to provide thermal regulation of the heat source 204 as discussed herein. Additionally, the thermally conductive plastic support 212 may extend through one or more openings in the bottom chassis cover, as noted above, to form a thermally conductive heat path between the heat source 204 and the bottom chassis cover. Additionally, when the electronic device is disposed on a surface, the thermally conductive plastic support 212 is configured to form an additional conductive heat path between the heat source 204 and the surface upon which the electronic device 100 is disposed.

In other words, the thermally conductive plastic support 212 may facilitate the formation of thermally conductive heat paths that draw heat away from the heat source 204 and redistribute this heat throughout other components. That is, the thermally conductive plastic support(s) 212 may facilitate the removal of heat from the heat pipes 210 and the distribution of this removed heat through the overall structure of the thermally conductive plastic support 212, the bottom chassis cover and, when the the electronic device 100 is placed onto a surface, the surface as well. To do so, the thermally conductive plastic support 212 may have one portion that extends through the bottom chassis cover to contact the heat pipe(s) 210 at one or more locations, with the remaining portions of the thermally conductive plastic support 212 being in thermal contact with the bottom chassis cover as further discussed herein.

Again, the thermally conductive plastic support 212 may be comprised of any suitable type of thermally conductive polymer or other material for this purpose, which may have any suitable thermal conductivity. As one illustrative and non-limiting scenario, the thermally conductive plastic support 212 may be implemented as NYTEX thermal conductive plastic (CM5000), with a thermal conductivity coefficient K=5 W/m-K. The thermally conductive plastic support 212 may be homogeneous and be comprised of the same material, as noted above with respect to the NYTEX thermal conductive plastic (CM5000) or other suitable thermally conductive polymers.

Alternatively, the thermally conductive plastic support 212 may be a composite of any suitable number of different materials in addition to a thermally conductive plastic. As some illustrative and non-limiting scenarios, the thermally conductive plastic support 212 may be constructed with a thermally conductive plastic surface, which may include an inner structure that may not be thermally conductive. Such “inner” materials may include thermoplastic polyurethane (PTU), mylar, other suitable polymers, etc. Thus, the surface of the thermally conductive plastic support 212 may be comprised of a thermally conductive plastic having any suitable thickness to facilitate the formation of the various heat paths as discussed herein. However, the remaining material of the thermally conductive plastic support 212, i.e. the material beneath the thermally conductive surface, may be non-thermally conducive. As the heat path is formed primarily on the surface of the thermally conductive plastic support 212 in any event, such aspects may be particularly useful to reduce the cost of the thermally conductive plastic support 212 and/or when properties of other materials (strength, durability, etc.) are desirable in addition to thermal conductivity.

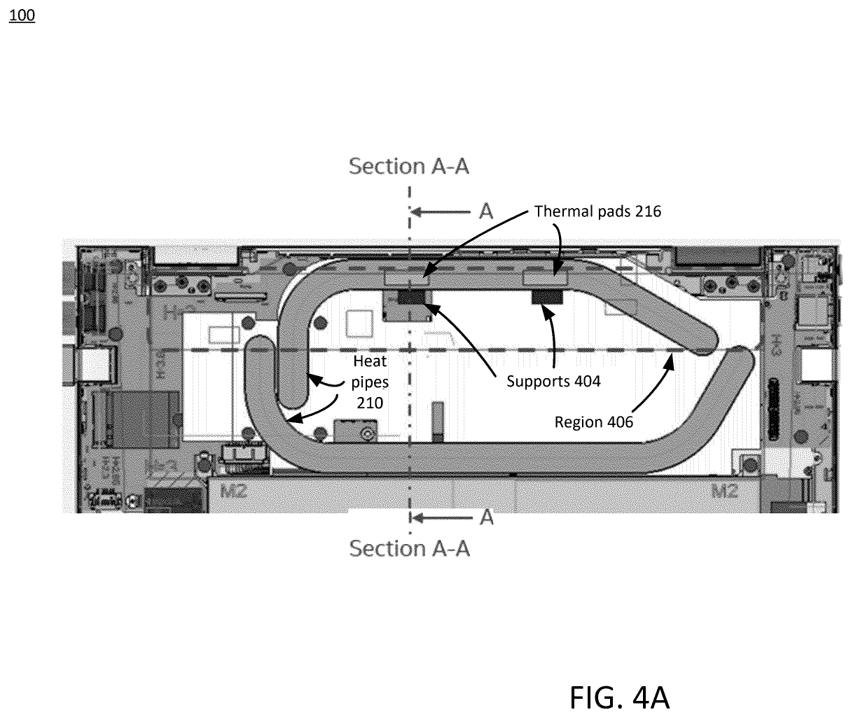

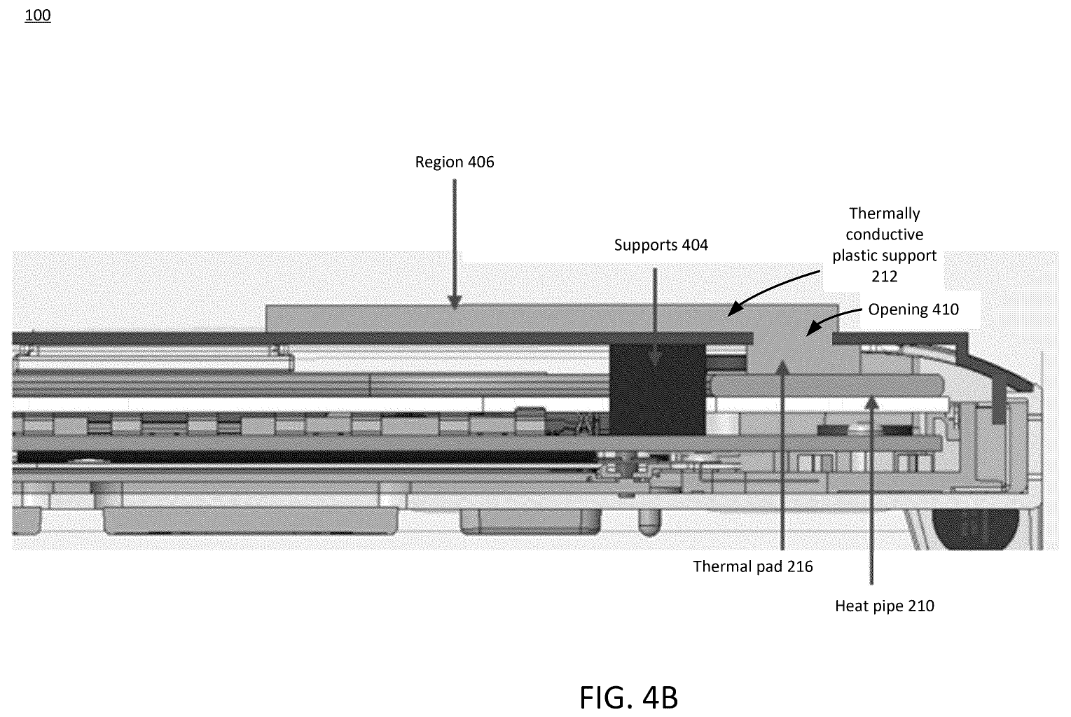

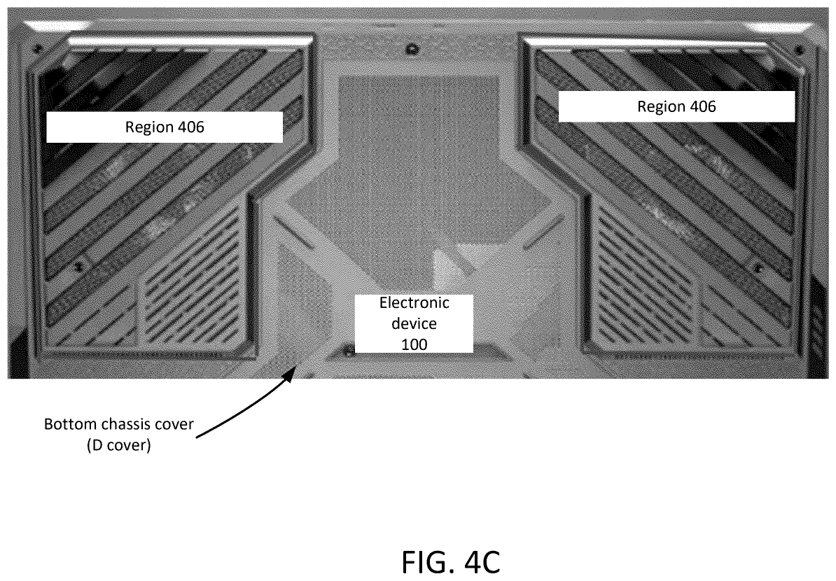

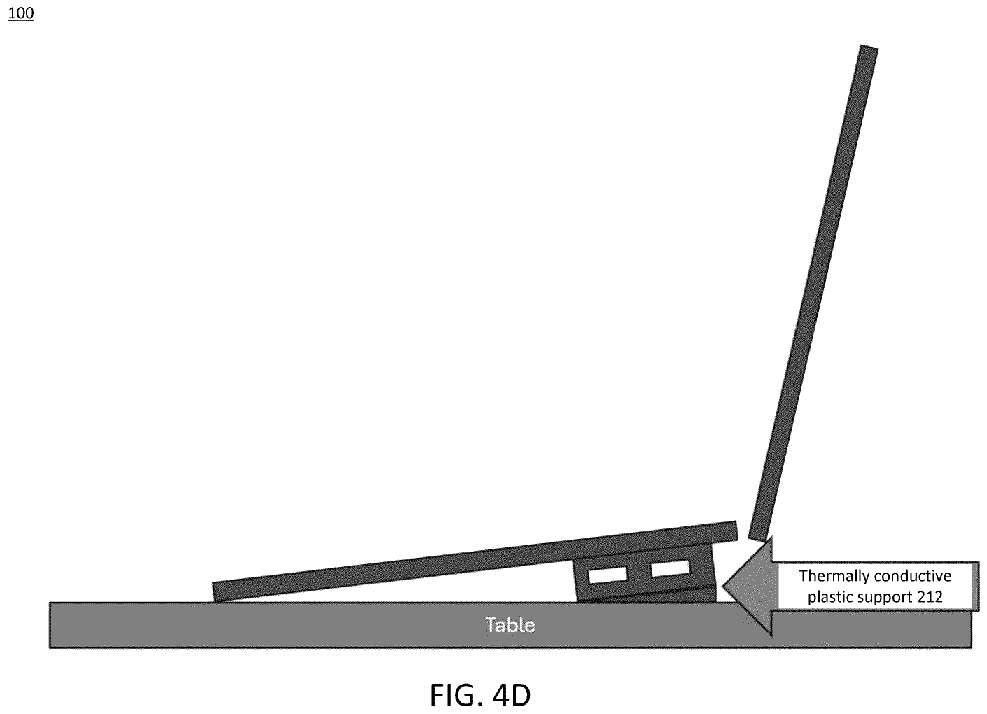

Additional detail regarding the electronic device 100 and the accompanying cooling system is provided in FIGS. 4A-4D. FIG. 4A illustrates a view from the bottom of the electronic device 100 without the bottom chassis cover in place. Thus, the view as shown in FIG. 4A includes a region 406 that represents an overlay onto a location on the bottom of the electronic device 100 where the entirety or a portion of the thermally conductive plastic support 212 may be disposed. As another non-limiting and illustrative scenario, the electronic device 100 is shown in FIG. 4C with regions 406 identified with the locations of several thermally conductive plastic supports 212.

FIG. 4D shows an alternate placing of the thermally conductive plastic support 212 for the electronic device 100, which may be particularly useful for laptop designs having an input/output (I/O) “bump” that accommodates an I/O port. For such designs, a system fan is typically placed in this region to provide cooling for the heat source 204. The fan in this region may be replaced with the cooling module 250 as discussed herein, which may include coupling the heat pipes 210 to the thermally conductive plastic support 212 in this region. The thermally conductive plastic support 212 may thus provide an additional conductive heat path via contact with a surface when the electronic device 100 is placed on that surface, as shown in FIG. 4D.

Thus, the electronic device 100 may include any suitable number of thermally conductive plastic supports 212, which may have any suitable size and shape, any number of which being implemented within the regions 406 as shown. The view as shown in FIG. 4A also illustrates the heat pipes 210 as discussed above with respect to FIGS. 2 and 3A, as well as thermal pads 216. The thermal pads 216 may correspond to locations on the surface of the heat pipes 210 that are in contact with one or more respective portions of the thermally conductive plastic support 212, as shown in FIGS. 2 and 4B. The thermal pads 216 may represent any suitable thermal interface material, such as thermal paste or pads, that are disposed onto these specific regions of the heat pipes 210. Thus, the cooling system 105 of the electronic device 100 may comprise any suitable number of such thermal pads 216, each being thermally coupled and in physical contact with a respective portion of one or more thermally conductive plastic supports 212. As a result, the thermal pads 216 may be disposed on the heat pipes 210 to align with the openings 410 in the bottom chassis cover, which is shown in further detail by way of in FIG. 4B, which shows further detail with respect to the cross-section A-A as shown in FIG. 4A.

As shown in FIGS. 4A-4B, the electronic device 100 may optionally include one or more supports 404, which may be implemented as any suitable material. Thus, the supports 404 may, but need not be, implemented as thermally conductive plastic, or alternatively be implemented as non-thermally conductive plastic, rubber, etc. As shown in FIG. 4B, the supports 400 may be disposed between an inside of the bottom chassis cover and a location within the electronic device 100 that is proximate to the contact between each one of the thermally conductive plastic supports 212 and the heat pipes 210. That is, one of the supports 404 may be disposed proximate to each junction between the heat pipes 210 and the thermally conductive plastic supports 212 (such as proximate to each location of the thermal pads 216 as shown in FIG. 4A).

The supports 404 are configured to reduce the transfer of mechanical stress applied to the heat pipes 210 by way of the thermally conductive plastic support 212. In other words, the supports 404 are configured to eliminate or at least mitigate the deformation of the heat pipes 210 due to external mechanical stresses in light of the thermally conductive plastic supports 212 being mechanically coupled to portions of the heat pipes 210 as discussed herein. Thus, the supports 404 may be affixed as shown in FIG. 4B to form a support between the outer chassis cover of the electronic device 100 and a point within the electronic device 100 to provide effective mechanical stress relief, such as being coupled to the mainboard 202 as shown. The supports 404 may be implemented as any suitable type of material having sufficient strength, stiffness, etc., suitable for this purpose.

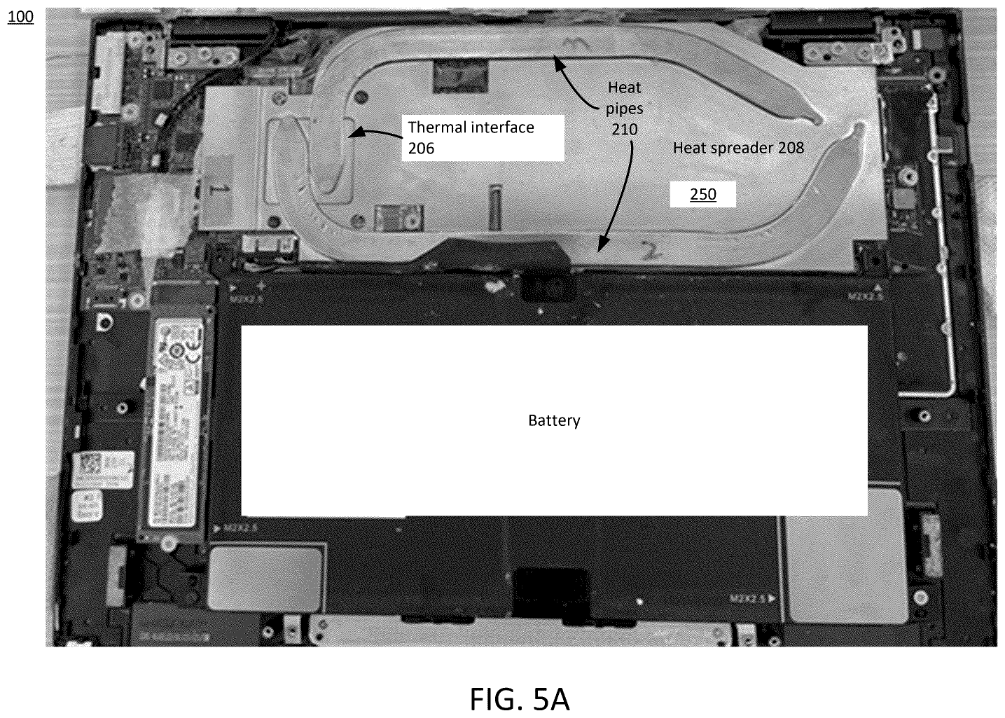

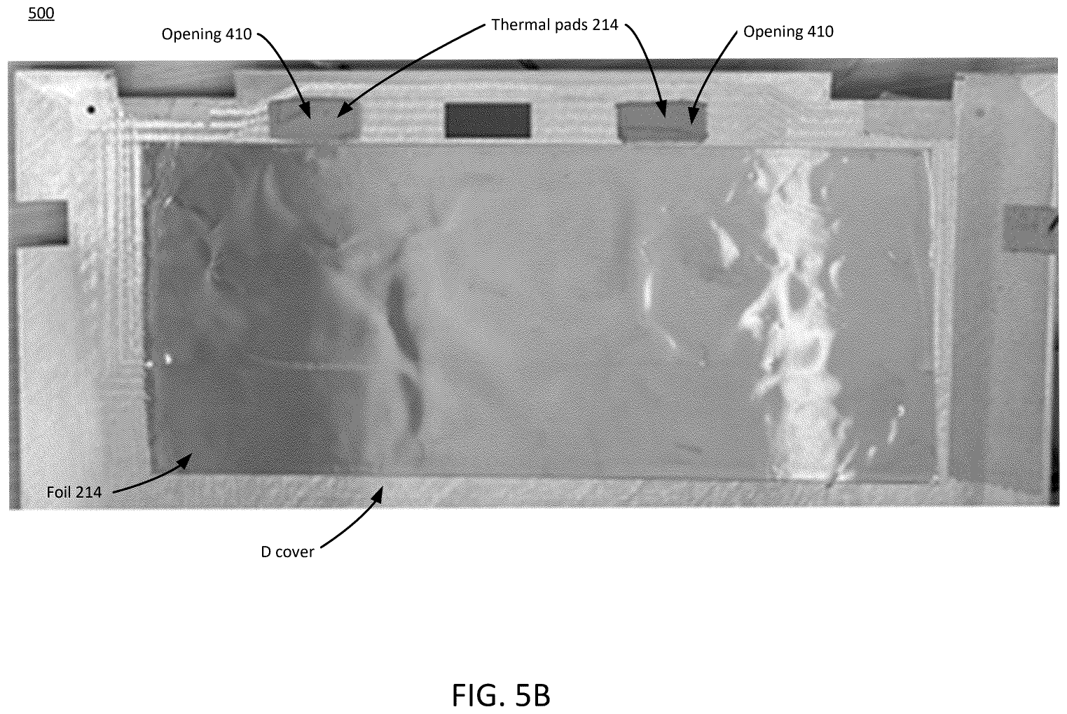

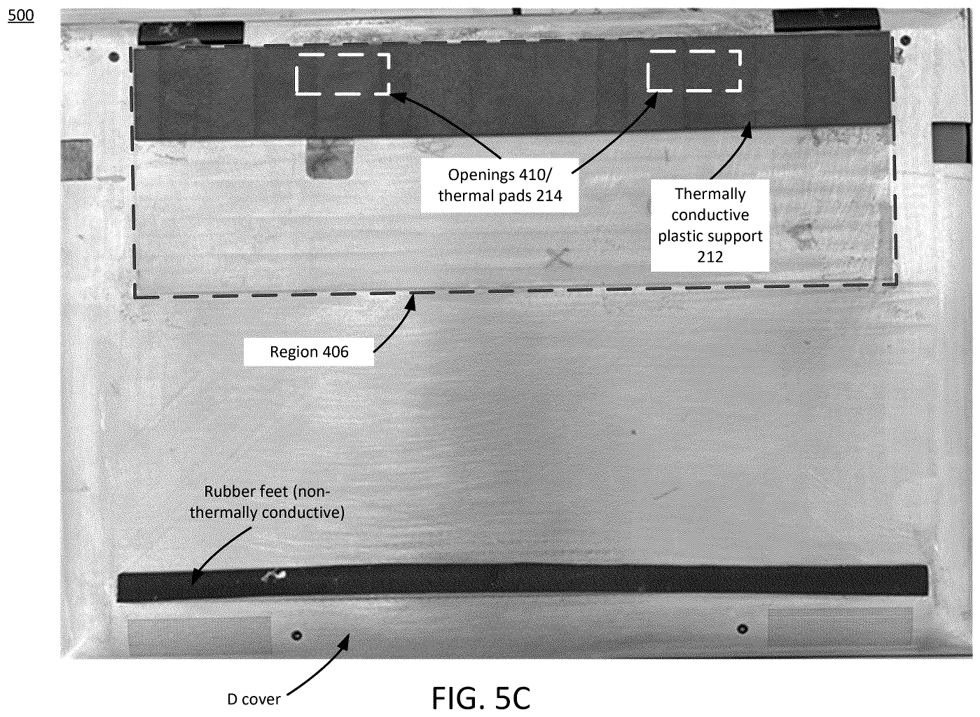

FIGS. 5A-5C illustrate various views showing the details of the interfaces between the cooling module and the electronic device, in accordance with the disclosure. Each of the FIGS. 5A-5C illustrates a different view of the electronic device 100 and the cooling module 250. For instance, FIG. 5A shows a view from the bottom of the electronic device 100 with the D cover removed. The cooling module 250 as shown in FIGS. 3A and 3B is also shown in FIG. 5A from this view, which again includes the heat pipes 210, the heat spreader 208, and the thermal interface 206. The electronic device 100 may include any suitable heat source 204, such as an SoC or a portion of an SoC as discussed above, which may be coupled to the other side of the thermal interface 206. However, the positioning of the cooling module 250 as shown in FIG. 5A obscures the view of the heat source 204.

Additionally, FIG. 5B illustrates a view of the D cover of the electronic device 100, which may be disposed over the components as shown in FIG. 5A. Thus, the view in FIG. 5B shows the side of the D cover that interfaces with the cooling module 250 as shown in FIG. 5A when installed as part of the electronic device 100. The view as shown in FIG. 5B includes the optional foil 214, as shown and discussed above with respect to FIG. 2. Again, when present, the foil 214 may provide an additional conductive heat path from the heat source 204 via the thermally conductive plastic support 212.

FIG. 5C shows a view from the bottom of the electronic device 100 once the D cover as shown in FIG. 5B is installed onto cooling module 250 as shown in FIG. 5A and onto the bottom of the electronic device 100. Thus, the view of FIG. 5C illustrates the rubber feet of the electronic device 100, which may be non-thermally conductive, as well as the region 406 within the D cover as shown and discussed above with respect to FIGS. 4A-4C. Within the region 406, the D cover as shown in FIG. 5C also includes the thermally conductive plastic support 212 that is disposed onto the D cover as shown. The thermally conductive plastic support 212, which may have any suitable size and shape, with a single rectangular shape being shown. Again, the thermally conductive plastic support 212 may be disposed within the region 406 such that portions of the thermally conductive plastic support 212 align with the openings 410 in the D cover and the accompanying thermal pads 216, as shown in FIG. 5B. Again, the thermal pads 216 allow these portions of the thermally conductive plastic support 212 (denoted via the white dashed boxes in the region 406) to be in physical and thermal contact with the corresponding portions of the heat pipes 210, as shown in FIG. 5A, which are exposed through the openings 410 in the D cover and may also include the thermal pads 216 applied thereto, as shown in FIG. 5B. In this way, a conductive heat path is formed from the heat source 204 to the heat pipes 210 by way of the cooling module 250, and in turn the conductive heat path is further formed between the heat pipes 210 and the thermally conductive plastic support 212 at the bottom of the D cover. The conductive heat path may further extend to the D cover itself as well as any surface onto which the D cover is disposed, as shown in FIG. 2.

As a result, the thermally conductive plastic support 212 may enable improved thermal management for a fanless or fanless capable design of the electronic device 100 by providing additional conductive heat paths to cool the heat source 204. However, it is noted that the position and/or usage of the electronic device 100 may yield better thermal performance than others given the additional conductive heat path that may be formed when the electronic device 100 is disposed on a surface, as shown in FIG. 2, as opposed to being removed from that surface.

Thus, reference is once again made to the electronic device 100 as shown in FIG. 1, which may include any suitable number N of sensors 103.1-103.N. The sensors 103.1-103.N may be implemented as any suitable type of sensor, each being configured to generate sensor data in accordance with a particular type of sensor measurement. The processing circuitry 104, which again may be identified with one or more portions (or the entirety) of the SoC of the electronic device 100 as discussed herein, is configured to receive and process the sensor data generated via the sensors 103.1-103.N. Additionally, the processing circuitry 104 may, in response to this sensor data processing, adjust the power profile of the electronic device 100 and an accompanying TDP setting when the sensor data indicates that one or more triggering conditions have been met.

The adjustment of the power profile of the electronic device 100 and the accompanying TDP setting may be performed in any suitable manner in response to the sensor data, which may include the implementation of hardware, software, or a combination of these. As one non-limiting and illustrative scenario, the electronic device 100 may utilize the processing circuitry 104 as a hardware-based solution to monitor the sensor data and to cause the electronic device 100 to adjust a power profile and an accompanying TDP setting in response to the sensor data. As another non-limiting and illustrative scenario, and as noted above, the adjustable TDP control module 109 may store computer-readable instructions that, when executed by the processing circuitry 104, enable the electronic device 100 to monitor the sensor data and to cause the electronic device 100 to adjust a power profile and an accompanying TDP setting in response to the sensor data. In any event, the processing circuitry 104 may, as a hardware-based solution or via execution of the instructions stored in the adjustable TDP control module 109, receive and analyze the sensor data, determine whether one or more triggering conditions have been met and, if so, to generate control signals to adjust the power profile of the electronic device 100 and the accompanying TDP setting.

To provide an illustrative and non-limiting scenario, the electronic device 100 may be configured to operate in accordance with different power profiles, which may also be referred to as modes, such as a power/performance operating mode, a battery operating mode when the electronic device 100 is disconnected from an AC power source, etc. The electronic device 100 may be configured to operate in accordance with any suitable number of such modes, with each mode being identified with a respective TDP. The TDP is understood as meaning the maximum amount of heat generated by a particular component (such as the SoC) that the cooling system 150 is designed to dissipate under any workload. Thus, the electronic device 100 may be configured to operate in accordance with a higher TDP for the power/performance operating mode compared to the battery operating mode. As some illustrative and non-limiting scenarios, the TDP for the battery operating mode may be 13 W, whereas the TDP for the power/performance operating mode may be 15 W. Of course, the number of modes and corresponding TDP settings are provided for clarity and illustrative purposes, and the electronic device may operate in accordance with a greater number of modes and/or different TDP settings per mode.

In any event, the processing circuitry 104 may be configured to adjust the TDP of the electronic device 100 in response to one or more triggering conditions being met. Such conditions may include, for instance, detecting a particular use case scenario based upon an analysis of the sensor data. The TDP may be adjusted, in some non-limiting and illustrative scenarios, by causing the electronic device 100 to enter into a specific mode of operation as discussed above, which is known to be identified with a corresponding TDP setting. Thus, the processing circuitry 104 may cause the electronic device 100 to enter into a specific mode of operation that may override the typical use of a particular mode of operation. For instance, the electronic device 100 may enter into a battery operating mode of operation to reduce the TDP setting despite the electronic device 100 still being connected to an AC power source. In this way, the electronic device 100 may leverage the use of predefined power profile settings to ensure that the cooling system 150, when implemented as part of a fanless or fanless capable design, provides adequate cooling but does not cause the surface temperature of the electronic device 100 to exceed regulatory skin temperature safety thresholds.

Thus, and to provide some non-limiting and illustrative scenarios, the processing circuitry 104 may be configured to determine, from the sensor data, whether the electronic device 100 is disposed on a surface, which may include any suitable surface other than a user. Thus, the sensors 103.1-103.N may comprise proximity sensors, infrared sensors, ultrasonic sensors, thermal sensors, accelerometers, etc., that may enable the processing circuitry 104 to make this determination. Thus, the sensors 103.1-103.N, the sensor data generated via the sensors 103.1-103.N, as well as the manner in which the processing circuitry 104 may perform these determinations, may be implemented in accordance with any suitable techniques, including known techniques. As one illustrative and non-limiting scenario, the sensor data may indicate that the electronic device has been picked up from a surface or that the electronic device 100 has been placed onto a flat, level surface. In this way, the processing circuitry 104 may detect, based upon the sensor data generated via the sensors 103.1-103.N, when the electronic device 100 is placed on a surface and removed from that surface.

In response, the processing circuitry 104 may cause the electronic device 100 to operate in accordance with a higher TDP setting (such as by entering the power/performance mode of operation) when it is detected that the electronic device 100 is placed on a surface. This is preferable because, in such a scenario, the surface provides an additional conductive heat path to increase the cooling efficiency of the cooling system 105. Additionally, there is no concern with respect to the skin temperature safety thresholds being exceeded when the electronic device 100 is on an inorganic surface, as any increase in surface temperature of the bottom of the D cover is of less consequence.

However, the processing circuitry 104 may cause the electronic device 100 to operate in accordance with a lower TDP setting (such as by entering the battery mode of operation) when it is detected that the electronic device 100 is removed from or otherwise is not disposed on a surface. This is preferable because, in such a scenario, the cooling efficiency of the cooling system 105 is reduced by way of the loss of the additional conductive heat path. Furthermore, once removed, there is the added concern with respect to the skin temperature safety thresholds being exceeded, as the electronic device 100 may potentially come into contact with a user.

### II. A Process Flow

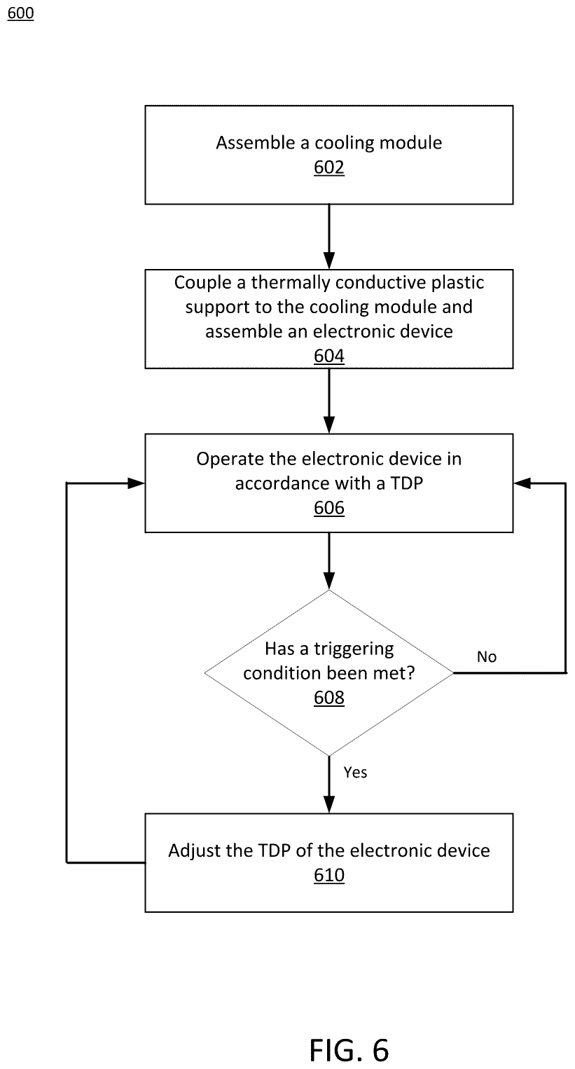

FIG. 6 illustrates a process flow, in accordance with the present disclosure. With reference to FIG. 6, the flow 600 may be a manual process, a fully-automated process, or a partially-automated process. When fully or partially automated, any portion or the entirety of the flow 600 may be implemented as a computer-implemented process executed by and/or otherwise associated with one or more processors. These processors may be associated with one or more computing components identified with any suitable computing device, such as a computing device or manufacturing component configured to perform such functionality. The one or more processors identified with one or more of the computing components as discussed herein may execute instructions stored on any suitable computer-readable storage medium. The flow 600 may include alternate or additional steps that are not shown in FIG. 6 for purposes of brevity, and may be performed in a different order than the steps shown in FIG. 6.

Flow 600 may begin by assembling (block 602) a cooling module. This may include assembling a cooling module, such as the cooling module 250 as discussed herein.

The flow 600 may further comprise coupling (block 604) a thermally conductive plastic support to the cooling module to assemble (block 604) an electronic device. This may include assembling the cooling module 250 as part of the electronic device 100, as discussed above, which may also include coupling the D cover and thermally conductive plastic support 212 as discussed above with respect to FIGS. 5A-5C.

The flow 600 may further comprise operating (block 606) the electronic device. This may include operating the electronic device 100 in accordance with a particular TDP, as discussed above.

The flow 600 may further comprise determining (block 608) whether a triggering condition has been met. This may include, for instance, detecting a particular use case scenario or a change in as current use scenario based upon an analysis of the sensor data, as discussed above, which may include detecting whether the electronic device 100 is currently disposed on a surface or removed from the surface. If no triggering condition has been met, then the flow 600 continues with the electronic device 100 operating in the current TDP setting.

However, if the triggering condition has been met, then the flow 600 may further comprise adjusting (block 610) the TDP based upon the particular detected condition. Again, this may include adjusting the TDP to increase or decrease the TDP based upon whether the electronic device 100 is detected as being on or removed from a surface, as noted above.

### III. Performance of the Cooling System

Again, the cooling system as discussed herein may facilitate a fanless or fanless capable electronic device design and allow for higher TDPs of operation by way of the use of the thermally conductive plastic support 212 providing a conductive heat path. To demonstrate the effectiveness of a fanless design, this Section provides several metrics related to thermal performance of an illustrative electronic device implementing the cooling system 105 as discussed herein.

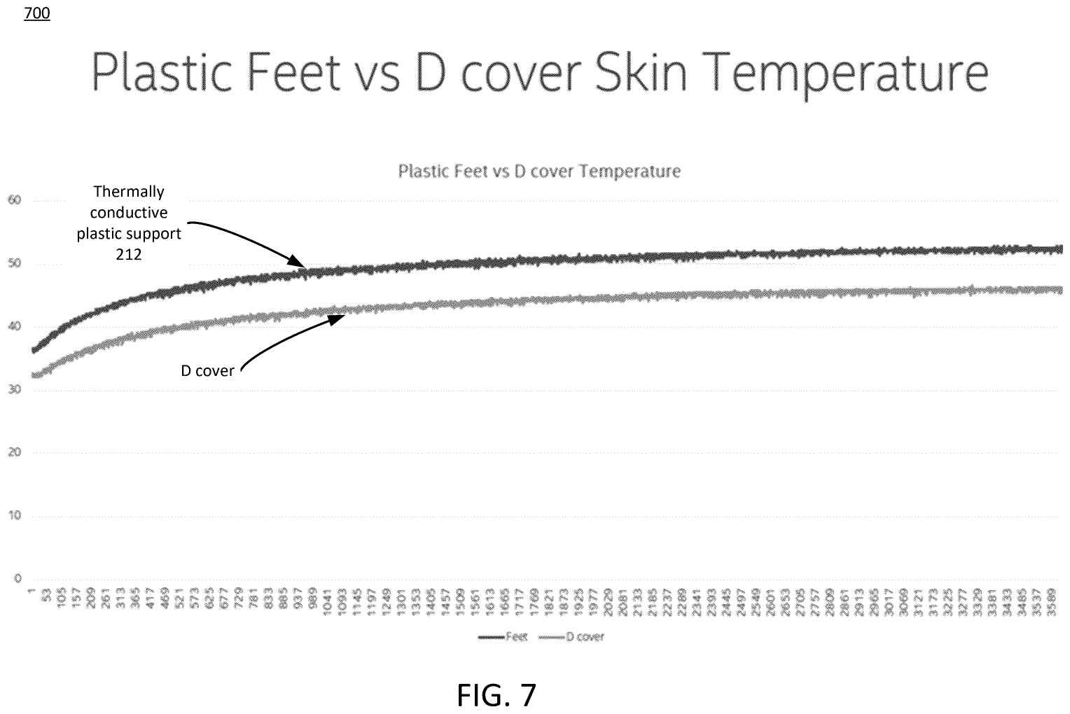

FIG. 7 illustrates the temperature of the thermally conductive plastic support 212 and the D cover when the electronic device 100 is running at 15 W TDP for approximately one hour. Thus, FIG. 7 illustrates that, when the electronic device 100 is not disposed on a surface but still running at an increased 15 W TDP, the temperature of the thermally conductive plastic support 212 is maintained at about 52.5° C., whereas the surface temperature of the D cover is maintained at about 46° C. Thus, skin temperature specifications may be met regardless of whether the electronic device 100 is disposed on a surface, which is a result of the conductive heat path provided by way of the thermally conductive plastic support 212 being coupled to the heat pipe(s) 210 of the cooling module 250, as noted herein, which enables heat to be wicked away from the heat source 204 and distributed into the D cover.

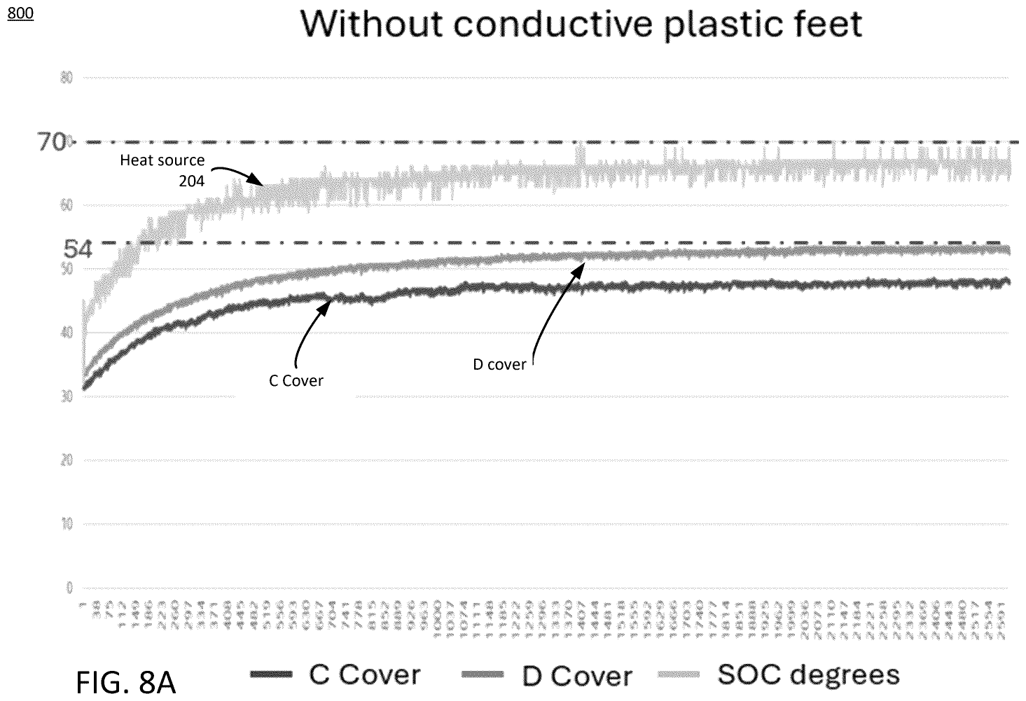

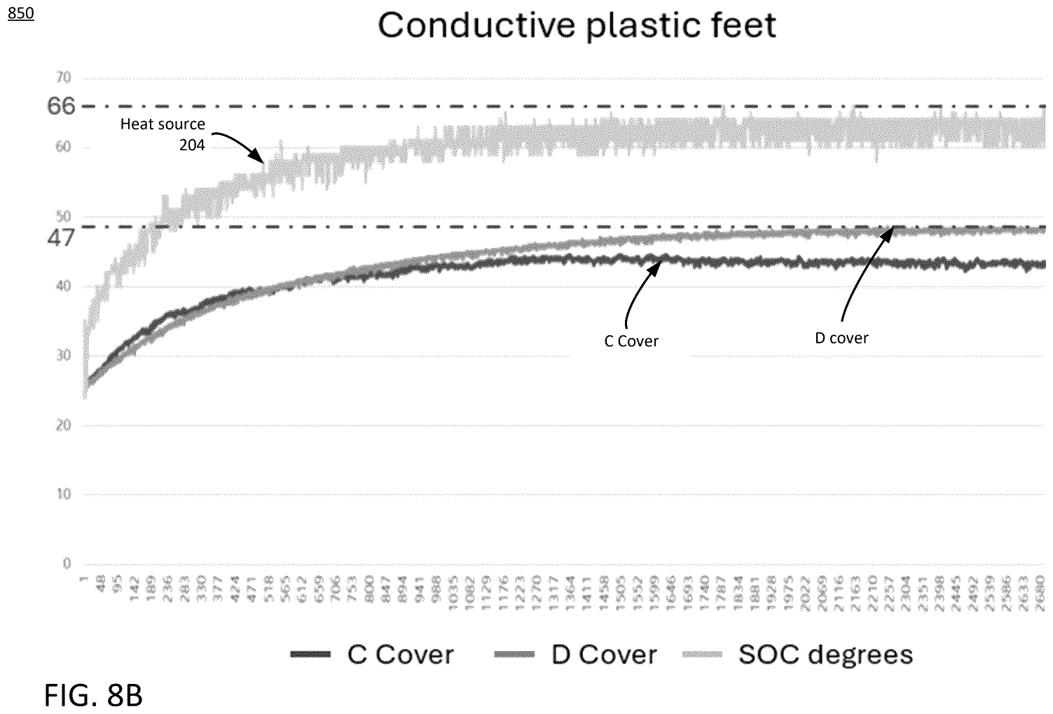

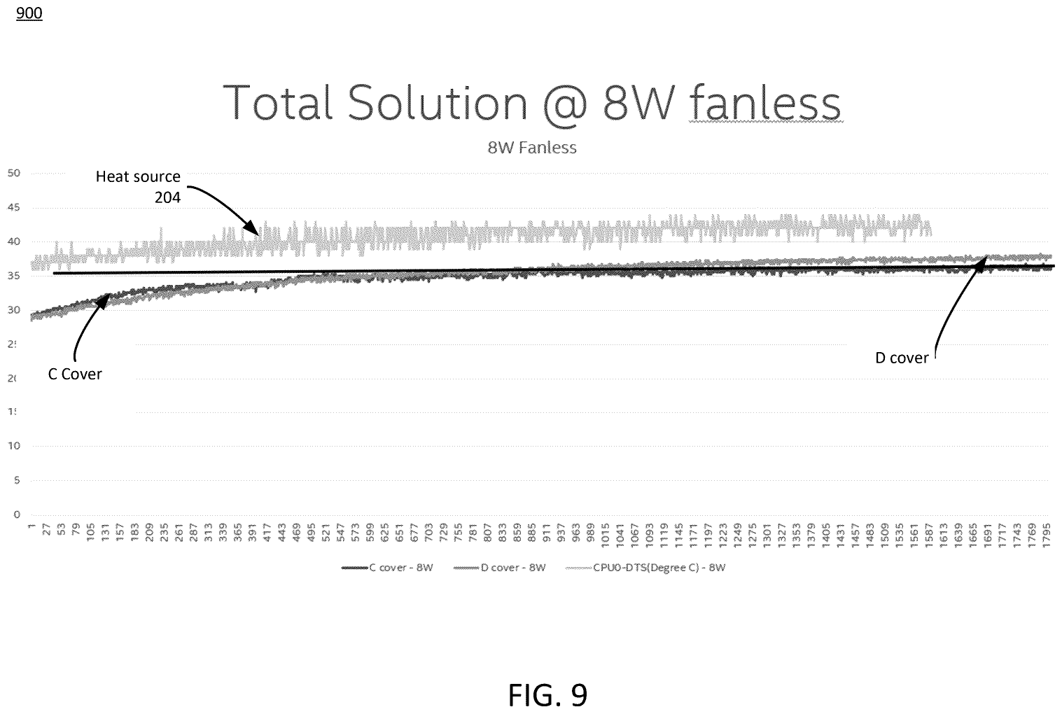

FIGS. 8A and 8B illustrate the improved thermal performance by way of the use of the cooling system 150 as discussed herein. FIGS. 8A and 8B represent the temperature of the heat source 204, the C cover, and the D cover when the electronic device 100 is running at 15 W TDP for approximately 43 minutes. For the tests performed with respect to both FIGS. 8A and 8B, the electronic device 100 was disposed on a wooden table surface. FIG. 8A illustrates the temperature of the heat source 204, the C cover, and the D cover of the electronic device 100 without the conductive plastic support 212 and the cooling system 105 as discussed herein. FIG. 8B, on the other hand, illustrates the temperature of the heat source 204, the C cover, and the D cover of the electronic device 100 with the conductive plastic support 212 and the cooling system 105 as discussed herein. From a comparison of FIGS. 8A and 8B, it may be observed that the temperatures of the SoC and D cover drop significantly when the conductive plastic support 212 is used in conjunction with the cooling system 105.

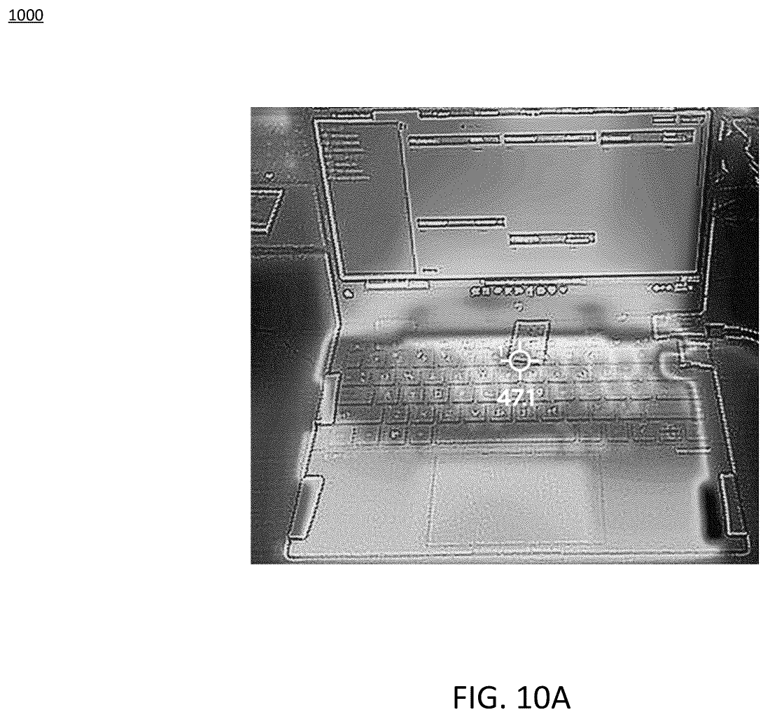

FIG. 9 illustrates the temperature of the heat source 204, the C cover, and the D cover when the electronic device 100 is running at 8 W TDP for approximately 30 minutes as part of a fanless design. This fanless design may also utilize conductive plastic support 212 in conjunction with the cooling system 105. As shown in FIG. 9, the result is that the SoC Tj (the heat source 204) was about 44° C., and the temperatures of C cover and D cover were 35° C. degrees and 37° C. degrees, respectively.

Next, the TDP of the electronic device 100 was increased to 15 W, 17 W, and 20 W by 20 minutes under the same test conditions. From the test results shown in Table 1 below, it is observed that the Tj of the SoC rises to 60 degrees at 15 W, and the temperatures of C and D covers are 41° C. and 43.5° C. Thus, it is possible for the temperatures of the C and D covers to pass thermal test specifications. This result proves that such a solution can fully support a 15 W TDP fanless design.

TABLE 1

| | | | |
|---|---|---|---|
| TDP | 15 W | 17 W | 20 W |

| | | | | | | |
|---|---|---|---|---|---|---|
| SoC (Tj) | 60° | C. | 70° | C. | 75° | C. |
| C Cover (T) | 41° | C. | 44° | C. | 47° | C. |
| D Cover (T) | 43.5° | C. | 49° | C. | 50° | C. |

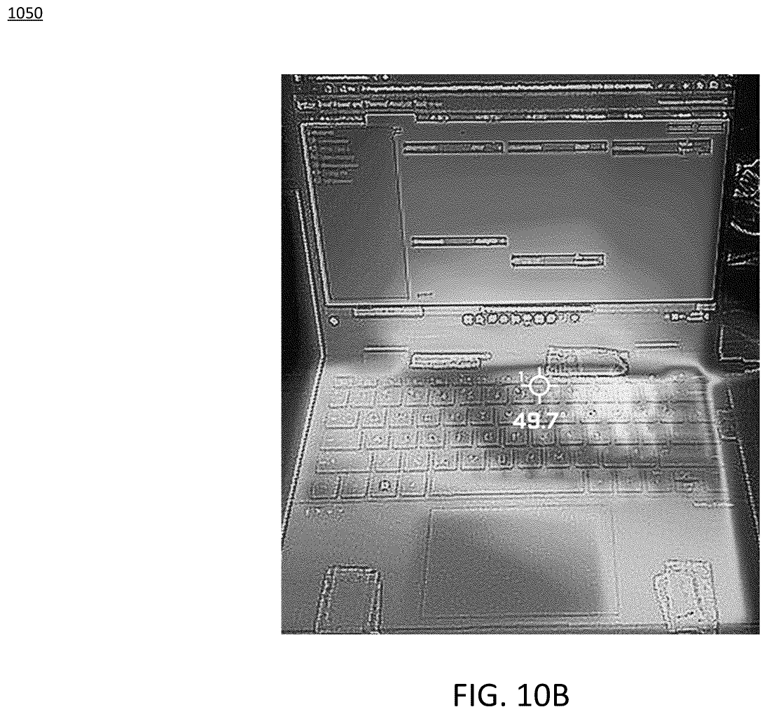

FIGS. 10A and 10B illustrate IR thermal images of the electronic device 100 for fanless and fan-based designs. FIG. 10A illustrates an IR thermal image of the electronic device 100 operating at 15 W TDP with the use of the cooling system 150 as discussed herein as part of a fanless design, which shows that the cooling module 250's heat dissipation is very even and does not concentrate the heat on a certain point on the system.

In contrast, FIG. 10B corresponds to an IR thermal image of the electronic device 100 operating at 15 W TDP without the use of the cooling system 150 as discussed herein, which instead uses a conventional fan-based design. In FIG. 10B, it is observed that the heat is completely concentrated on the right side even with a fan present, and the maximum temperature (49.7° C.) is still higher than the fanless design (47.1° C.) as shown in FIG. 10A.

### IV. General Configuration of an Electronic Device

An electronic device is provided. The electronic device comprises a bottom chassis cover including an opening, and a thermally conductive plastic support configured to extend through the opening in the bottom chassis cover and to contact a heat pipe of the electronic device. The heat pipe is coupled to a heat source of the electronic device, and the thermally conductive plastic support is configured to provide a conductive heat path between the heat source and the bottom chassis cover. In addition or in alternative to and in any combination with the optional features previously explained in this paragraph, the electronic device further comprises a system on a chip (SoC), and the heat source comprises a portion of the SoC. In addition or in alternative to and in any combination with the optional features previously explained in this paragraph, the electronic device comprises a laptop computer. In addition or in alternative to and in any combination with the optional features previously explained in this paragraph, the laptop computer is a fanless or fanless capable laptop computer. In addition or in alternative to and in any combination with the optional features previously explained in this paragraph, the laptop computer is configured to operate at a thermal design power (TDP) of up to about 15 Watts. In addition or in alternative to and in any combination with the optional features previously explained in this paragraph, the electronic device further comprises a cooling module comprising a metal plate coupled to the heat pipe, and the metal plate is configured to spread heat generated by the heat source across the metal plate. In addition or in alternative to and in any combination with the optional features previously explained in this paragraph, the thermally conductive plastic support comprises a supportive foot of the electronic device that is configured to contact a surface upon which the electronic device is disposed. In addition or in alternative to and in any combination with the optional features previously explained in this paragraph the thermally conductive plastic support is configured to provide a further conductive heat path between the heat source and the surface. In addition or in alternative to and in any combination with the optional features previously explained in this paragraph, the electronic device further comprises a non-thermally conductive support disposed proximate to a point of contact between the thermally conductive plastic support and the heat pipe, and the non-thermally conductive support is configured to reduce mechanical stress transferred to the heat pipe via the thermally conductive plastic support. In addition or in alternative to and in any combination with the optional features previously explained in this paragraph, the electronic device further comprises a sensor configured to generate sensor data, and the SoC is configured to adjust a thermal design power (TDP) of the electronic device based upon the sensor data. In addition or in alternative to and in any combination with the optional features previously explained in this paragraph, the SoC is configured to increase the TDP of the electronic device upon detecting, based upon the sensor data, that the electronic device is disposed on a surface. In addition or in alternative to and in any combination with the optional features previously explained in this paragraph, the SoC is configured to decrease the TDP of the electronic device upon detecting, based upon the sensor data, that the electronic device is not disposed on the surface.

### V. General Configuration of a Cooling System

A cooling system is provided. The cooling system comprises a cooling module comprising a metal plate coupled to a heat pipe, the heat pipe is coupled to a heat source of an electronic device, and further includes a thermally conductive plastic support configured to extend through an opening in the electronic device and to contact the heat pipe. The thermally conductive plastic support is configured to provide a conductive heat path between the heat source and a bottom chassis cover of the electronic device. In addition or in alternative to and in any combination with the optional features previously explained in this paragraph, the heat source comprises a portion of a system on a chip (SoC) of the electronic device. In addition or in alternative to and in any combination with the optional features previously explained in this paragraph, the metal plate is configured to spread heat generated by the heat source across the metal plate. In addition or in alternative to and in any combination with the optional features previously explained in this paragraph, the thermally conductive plastic support comprises a supportive foot of the electronic device that is configured to contact a surface upon which the electronic device is disposed. In addition or in alternative to and in any combination with the optional features previously explained in this paragraph, the thermally conductive plastic support is configured to provide a further conductive heat path between the heat source and the surface. In addition or in alternative to and in any combination with the optional features previously explained in this paragraph, the SoC is configured to adjust a thermal design power (TDP) of the electronic device based upon sensor data generated via a sensor of the electronic device. In addition or in alternative to and in any combination with the optional features previously explained in this paragraph, the SoC is configured to increase the TDP of the electronic device upon detecting that the electronic device is disposed on a surface. In addition or in alternative to and in any combination with the optional features previously explained in this paragraph, the SoC is configured to decrease the TDP of the electronic device upon detecting that the electronic device is not disposed on the surface.

### Examples

The following examples pertain to various techniques of the present disclosure.

An example (e.g. example 1) is directed to an electronic device, comprising: a bottom chassis cover including an opening; and a thermally conductive plastic support configured to extend through the opening in the bottom chassis cover and to contact a heat pipe of the electronic device, the heat pipe being coupled to a heat source of the electronic device, wherein the thermally conductive plastic support is configured to provide a conductive heat path between the heat source and the bottom chassis cover.

Another example (e.g. example 2), relates to a previously-described example (e.g. example 1), further comprising: a system on a chip (SoC), wherein the heat source comprises a portion of the SoC.

Another example (e.g. example 3) relates to a previously-described example (e.g. one or more of examples 1-2), wherein the electronic device comprises a laptop computer.

Another example (e.g. example 4) relates to a previously-described example (e.g. one or more of examples 1-3), wherein the laptop computer is a fanless or fanless capable laptop computer.

Another example (e.g. example 5) relates to a previously-described example (e.g. one or more of examples 1-4), wherein the laptop computer is configured to operate at a thermal design power (TDP) of up to about 15 Watts.

Another example (e.g. example 6) relates to a previously-described example (e.g. one or more of examples 1-5), further comprising: a cooling module comprising a metal plate coupled to the heat pipe, wherein the metal plate is configured to spread heat generated by the heat source across the metal plate.

Another example (e.g. example 7) relates to a previously-described example (e.g. one or more of examples 1-6), wherein the thermally conductive plastic support comprises a supportive foot of the electronic device that is configured to contact a surface upon which the electronic device is disposed.

Another example (e.g. example 8) relates to a previously-described example (e.g. one or more of examples 1-7), wherein the thermally conductive plastic support is configured to provide a further conductive heat path between the heat source and the surface.

Another example (e.g. example 9) relates to a previously-described example (e.g. one or more of examples 1-8), further comprising: a non-thermally conductive support disposed proximate to a point of contact between the thermally conductive plastic support and the heat pipe, wherein the non-thermally conductive support is configured to reduce mechanical stress transferred to the heat pipe via the thermally conductive plastic support.

Another example (e.g. example 10) relates to a previously-described example (e.g. one or more of examples 1-9), further comprising: a sensor configured to generate sensor data, wherein the SoC is configured to adjust a thermal design power (TDP) of the electronic device based upon the sensor data.

Another example (e.g. example 11) relates to a previously-described example (e.g. one or more of examples 1-10), wherein the SoC is configured to increase the TDP of the electronic device upon detecting, based upon the sensor data, that the electronic device is disposed on a surface.

Another example (e.g. example 12) relates to a previously-described example (e.g. one or more of examples 1-11), wherein the SoC is configured to decrease the TDP of the electronic device upon detecting, based upon the sensor data, that the electronic device is not disposed on the surface.

An example (e.g. example 13) is directed to a cooling system, comprising: a cooling module comprising a metal plate coupled to a heat pipe, the heat pipe being coupled to a heat source of an electronic device; and a thermally conductive plastic support configured to extend through an opening in the electronic device and to contact the heat pipe, wherein the thermally conductive plastic support is configured to provide a conductive heat path between the heat source and a bottom chassis cover of the electronic device.

Another example (e.g. example 14), relates to a previously-described example (e.g. example 13), wherein the heat source comprises a portion of a system on a chip (SoC) of the electronic device.

Another example (e.g. example 15) relates to a previously-described example (e.g. one or more of examples 13-14), wherein the metal plate is configured to spread heat generated by the heat source across the metal plate.

Another example (e.g. example 16) relates to a previously-described example (e.g. one or more of examples 13-15), the thermally conductive plastic support comprises a supportive foot of the electronic device that is configured to contact a surface upon which the electronic device is disposed.

Another example (e.g. example 17) relates to a previously-described example (e.g. one or more of examples 13-16), wherein the thermally conductive plastic support is configured to provide a further conductive heat path between the heat source and the surface.

Another example (e.g. example 18) relates to a previously-described example (e.g. one or more of examples 13-17), wherein the SoC is configured to adjust a thermal design power (TDP) of the electronic device based upon sensor data generated via a sensor of the electronic device.

Another example (e.g. example 19) relates to a previously-described example (e.g. one or more of examples 13-18), wherein the SoC is configured to increase the TDP of the electronic device upon detecting that the electronic device is disposed on a surface.

Another example (e.g. example 20) relates to a previously-described example (e.g. one or more of examples 13-19), wherein the SoC is configured to decrease the TDP of the electronic device upon detecting that the electronic device is not disposed on the surface.

An example (e.g. example 21) is directed to an electronic device, comprising: a bottom cover means including an opening; and a thermally conductive means extending through the opening in the bottom cover means and to contact a heat pipe of the electronic device, the heat pipe being coupled to a heat source of the electronic device, wherein the thermally conductive means provides a conductive heat path between the heat source and the bottom cover means.

Another example (e.g. example 22), relates to a previously-described example (e.g. example 21), further comprising: a system on a chip (SoC), wherein the heat source comprises a portion of the SoC.

Another example (e.g. example 23) relates to a previously-described example (e.g. one or more of examples 21-22), wherein the electronic device comprises a laptop computer.

Another example (e.g. example 24) relates to a previously-described example (e.g. one or more of examples 21-23), wherein the laptop computer is a fanless or fanless capable laptop computer.

Another example (e.g. example 25) relates to a previously-described example (e.g. one or more of examples 21-24), wherein the laptop computer is configured to operate at a thermal design power (TDP) of up to about 15 Watts.

Another example (e.g. example 26) relates to a previously-described example (e.g. one or more of examples 21-25), further comprising: a cooling means comprising a metal plate coupled to the heat pipe, wherein the metal plate is configured to spread heat generated by the heat source across the metal plate.

Another example (e.g. example 27) relates to a previously-described example (e.g. one or more of examples 21-26), wherein the thermally conductive means comprises a supportive foot of the electronic device that is configured to contact a surface upon which the electronic device is disposed.

Another example (e.g. example 28) relates to a previously-described example (e.g. one or more of examples 21-27), wherein the thermally conductive means provides a further conductive heat path between the heat source and the surface.

Another example (e.g. example 29) relates to a previously-described example (e.g. one or more of examples 21-28), further comprising: a non-thermally conductive support disposed proximate to a point of contact between the thermally conductive means and the heat pipe, wherein the non-thermally conductive support is configured to reduce mechanical stress transferred to the heat pipe via the thermally conductive means.

Another example (e.g. example 30) relates to a previously-described example (e.g. one or more of examples 21-29), further comprising: a sensor configured to generate sensor data, wherein the SoC is configured to adjust a thermal design power (TDP) of the electronic device based upon the sensor data.

Another example (e.g. example 31) relates to a previously-described example (e.g. one or more of examples 21-30), wherein the SoC is configured to increase the TDP of the electronic device upon detecting, based upon the sensor data, that the electronic device is disposed on a surface.

Another example (e.g. example 32) relates to a previously-described example (e.g. one or more of examples 21-31), wherein the SoC is configured to decrease the TDP of the electronic device upon detecting, based upon the sensor data, that the electronic device is not disposed on the surface.

An example (e.g. example 33) is directed to a cooling system, comprising: a cooling means comprising a metal plate coupled to a heat pipe, the heat pipe being coupled to a heat source of an electronic device; and a thermally conductive means configured to extend through an opening in the electronic device and to contact the heat pipe, wherein the thermally conductive means provides a conductive heat path between the heat source and a bottom chassis cover of the electronic device.

Another example (e.g. example 34), relates to a previously-described example (e.g. example 33), wherein the heat source comprises a portion of a system on a chip (SoC) of the electronic device.

Another example (e.g. example 35) relates to a previously-described example (e.g. one or more of examples 33-34), wherein the metal plate is configured to spread heat generated by the heat source across the metal plate.

Another example (e.g. example 36) relates to a previously-described example (e.g. one or more of examples 33-35), the thermally conductive means comprises a supportive foot of the electronic device that is configured to contact a surface upon which the electronic device is disposed.

Another example (e.g. example 37) relates to a previously-described example (e.g. one or more of examples 33-36), wherein the thermally conductive means provides a further conductive heat path between the heat source and the surface.

Another example (e.g. example 38) relates to a previously-described example (e.g. one or more of examples 33-37), wherein the SoC is configured to adjust a thermal design power (TDP) of the electronic device based upon sensor data generated via a sensor of the electronic device.

Another example (e.g. example 39) relates to a previously-described example (e.g. one or more of examples 33-38), wherein the SoC is configured to increase the TDP of the electronic device upon detecting that the electronic device is disposed on a surface.

Another example (e.g. example 40) relates to a previously-described example (e.g. one or more of examples 33-39), wherein the SoC is configured to decrease the TDP of the electronic device upon detecting that the electronic device is not disposed on the surface.

An apparatus as shown and described.

A method as shown and described.

### Conclusion

The aforementioned description will so fully reveal the general nature of the implementation of the disclosure that others can, by applying knowledge within the skill of the art, readily modify and/or adapt for various applications such specific implementations without undue experimentation and without departing from the general concept of the present disclosure. Therefore, such adaptations and modifications are intended to be within the meaning and range of equivalents of the disclosed implementations, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

Each implementation described may include a particular feature, structure, or characteristic, but every implementation may not necessarily include the particular feature, structure, or characteristic. Moreover, such phrases are not necessarily referring to the same implementation. Further, when a particular feature, structure, or characteristic is described in connection with an implementation, it is submitted that it is within the knowledge of one skilled in the art to affect such feature, structure, or characteristic in connection with other implementations whether or not explicitly described.

The exemplary implementations described herein are provided for illustrative purposes, and are not limiting. Other implementations are possible, and modifications may be made to the exemplary implementations. Therefore, the specification is not meant to limit the disclosure. Rather, the scope of the disclosure is defined only in accordance with the following claims and their equivalents.

Throughout the drawings, it should be noted that like reference numbers are used to depict the same or similar elements, features, and structures, unless otherwise noted.

The terms “at least one” and “one or more” may be understood to include a numerical quantity greater than or equal to one (e.g., one, two, three, four, [ . . . ], etc.). The term “a plurality” may be understood to include a numerical quantity greater than or equal to two (e.g., two, three, four, five, [ . . . ], etc.).

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. The terms “group (of)”, “set (of)”, “collection (of)”, “series (of)”, “sequence (of)”, “grouping (of)”, etc., and the like in the description and in the claims, if any, refer to a quantity equal to or greater than one, i.e., one or more. The terms “proper subset”, “reduced subset”, and “lesser subset” refer to a subset of a set that is not equal to the set, illustratively, referring to a subset of a set that contains less elements than the set.

The phrase “at least one of” with regard to a group of elements may be used herein to mean at least one element from the group consisting of the elements. The phrase “at least one of” with regard to a group of elements may be used herein to mean a selection of: one of the listed elements, a plurality of one of the listed elements, a plurality of individual listed elements, or a plurality of a multiple of individual listed elements.

What is claimed is:

1. An electronic device, comprising:
a bottom chassis cover including an opening; and
a thermally conductive plastic support configured to extend through the opening in the bottom chassis cover and to contact a heat pipe of the electronic device, the heat pipe being coupled to a heat source of the electronic device,
wherein the thermally conductive plastic support is configured to provide a conductive heat path between the heat source and the bottom chassis cover.

2. The electronic device of claim 1, further comprising:
a system on a chip (SoC),
wherein the heat source comprises a portion of the SoC.

3. The electronic device of claim 1, wherein the electronic device comprises a laptop computer.

4. The electronic device of claim 3, wherein the laptop computer is a fanless or fanless capable laptop computer.

5. The electronic device of claim 4, wherein the laptop computer is configured to operate at a thermal design power (TDP) of up to about 15 Watts.

6. The electronic device of claim 1, further comprising:
a cooling module comprising a metal plate coupled to the heat pipe,
wherein the metal plate is configured to spread heat generated by the heat source across the metal plate.

7. The electronic device of claim 1, wherein the thermally conductive plastic support comprises a supportive foot of the electronic device that is configured to contact a surface upon which the electronic device is disposed.

8. The electronic device of claim 7, wherein the thermally conductive plastic support is configured to provide a further conductive heat path between the heat source and the surface.

9. The electronic device of claim 1, further comprising:
a non-thermally conductive support disposed proximate to a point of contact between the thermally conductive plastic support and the heat pipe,
wherein the non-thermally conductive support is configured to reduce mechanical stress transferred to the heat pipe via the thermally conductive plastic support.

10. The electronic device of claim 2, further comprising:
a sensor configured to generate sensor data,
wherein the SoC is configured to adjust a thermal design power (TDP) of the electronic device based upon the sensor data.

11. The electronic device of claim 10, wherein the SoC is configured to increase the TDP of the electronic device upon detecting, based upon the sensor data, that the electronic device is disposed on a surface.

12. The electronic device of claim 11, wherein the SoC is configured to decrease the TDP of the electronic device upon detecting, based upon the sensor data, that the electronic device is not disposed on the surface.

13. A cooling system, comprising:
a cooling module comprising a metal plate coupled to a heat pipe, the heat pipe being coupled to a heat source of an electronic device; and
a thermally conductive plastic support configured to extend through an opening in the electronic device and to contact the heat pipe,
wherein the thermally conductive plastic support is configured to provide a conductive heat path between the heat source and a bottom chassis cover of the electronic device.

14. The cooling system of claim 13, wherein the heat source comprises a portion of a system on a chip (SoC) of the electronic device.

15. The cooling system of claim 13, wherein the metal plate is configured to spread heat generated by the heat source across the metal plate.

16. The cooling system of claim 13, wherein the thermally conductive plastic support comprises a supportive foot of the electronic device that is configured to contact a surface upon which the electronic device is disposed.

17. The cooling system of claim 16, wherein the thermally conductive plastic support is configured to provide a further conductive heat path between the heat source and the surface.

18. The cooling system of claim 14, wherein the SoC is configured to adjust a thermal design power (TDP) of the electronic device based upon sensor data generated via a sensor of the electronic device.

19. The cooling system of claim 18, wherein the SoC is configured to increase the TDP of the electronic device upon detecting that the electronic device is disposed on a surface.

20. The cooling system of claim 19, wherein the SoC is configured to decrease the TDP of the electronic device upon detecting that the electronic device is not disposed on the surface.
